(19) United States
(12) Patent Application Publication
(10) Pub. No.: US 2026/0260846 A1
(43) Pub. Date: Sep. 3, 2026

(54) Ion Milling Device

(71) Applicant: Hitachi High-Tech Corporation, Minato-ku, Tokyo (JP)

(72) Inventors: Shota AIDA, Tokyo (JP); Hisayuki TAKASU, Tokyo (JP); Naohiro FUJITA, Tokyo (JP)

(21) Appl. No.: 19/164,644

(22) PCT Filed: Mar. 22, 2023
(86) PCT No.: PCT/JP2023/011087

§ 371 Date: Sep. 12, 2025

(51) Int. Cl. H01J 37/305; H01J 37/20

(52) U.S. Cl. CPC H01J 37/3056; H01J 37/20

(57) ABSTRACT

An object of the present invention is to provide an ion milling device in which a horizontal movable stage is placed on a sample rotation stage and power can be supplied to the horizontal movable stage. The ion milling device according to the present invention includes a rotation stage, a movable stage provided on an upper surface of the rotation stage, and a fixed base unit supporting the rotation stage. The rotation stage includes a first power transmission unit, the fixed base unit includes a second power transmission unit. The ion milling device further includes a member that exerts a force for pressing the first power transmission unit and the second power transmission unit against each other (see FIG. 1C).

### TECHNICAL FIELD

The present invention relates to an ion milling device.

### BACKGROUND ART

An ion milling device irradiates a sample such as metal, semiconductor, glass, or ceramic which is an observation target of an electron microscope, with a non-converged ion beam. Through a sputtering phenomenon that occurs during ion beam irradiation to eject atoms of a sample surface, the sample surface can be polished without inducing stress or an internal structure of the sample can be exposed. Since the polished or exposed surface is an observation surface of a scanning electron microscope or a transmission electron microscope, the ion milling device is used as a preprocessing device for the samples.

There are a plurality of sample processing schemes using ion milling devices, but a scheme of irradiating the surface of a rotating sample with an ion beam at an angle to perform ion milling on the surface is referred to as a planar milling scheme. In addition to sample surface polishing, when a rotation center of the sample and a center of the ion beam are aligned and planar milling is performed, the sample can be processed into a conical shape. Therefore, in recent years, planar milling has been applied to delayering of semiconductor (flash memory).

With an increase in a capacity of flash memory in recent years, the demand for wide-area processing has increased. However, current milling schemes have no way to expand a processing range other than by shifting a processing position slightly and performing milling a plurality of times. Accordingly, there is concern of a processing time being prolonged.

PTL 1 below discloses a technique related to a sample stage in a charged particle beam device. PTL 1 addresses a problem of “enabling quick placement and exchange of a sample in a charged particle beam device” and discloses a technique in which “the charged particle beam device includes a charged particle beam column that irradiates the sample with a charged particle beam, a sample stage that includes a rotation stage 5A including a base unit 5d and a rotational movement unit rotating about a rotational axis R1 relative to the base unit 5d and that moves the sample relative to the charged particle beam column, a rotary connector 56 arranged coaxially with the rotational axis R1 and interposed between the base unit 5d and the rotational movement unit, and a contact pin 55a arranged above the sample stage and electrically connected to the rotary connector 56” (see Summary).

### CITATION LIST

### Patent Literature

PTL 1: JP2018-166042A

### SUMMARY OF INVENTION

### Technical Problem

In an ion milling device, in order to process a line shape using the planar milling scheme, it is necessary to implement a structure in which a stage rotation unit of the sample stage is placed at the bottom, and a sample movement stage (hereinafter referred to as a single-axis horizontal movable stage) is placed on the stage rotation unit. This is because a line shape can be formed by irradiating with the ion beam while rotating the rotation stage to sputter the sample into a conical shape, and simultaneously moving the processing position horizontally using the horizontal movable stage.

Since the horizontal movable stage moves horizontally using, for example, a motor, it is necessary to supply power to a drive mechanism. That is, it is necessary to connect a wiring for supplying power to the horizontal movable stage and supply power to the wiring. However, when the wiring is directly connected to a power supply, there is a possibility of the wiring being twisted as the stage rotates. Thus, when placing the horizontal movable stage on the rotation stage, it is considered that it is necessary to ensure the power path using a rotary contact.

In a rotary contact type wiring, mercury is used at the contact points to ensure a contact property. However, when such a rotary contact structure is brought into a sample chamber of an ion milling device, which operates under high vacuum (to 10⁻³ Pa or less), mercury sublimates. Therefore, it is difficult to use the rotary contact type wiring inside the sample chamber of an ion milling device.

PTL 1 describes a structure in which a single-axis horizontal movable stage is placed on top of a rotating body. However, it is considered that, in the structure disclosed in PTL 1, when a single-axis horizontal movable stage is placed on a sample rotational axis, there is a high risk of wiring being twisted and short-circuited, which makes it difficult to supply power. In PTL 1, there is a possibility of this issue not being sufficiently considered.

In view of the above problems, an object of the present invention is to provide an ion milling device in which a horizontal movable stage is placed on the sample rotation stage and power can be supplied to the horizontal movable stage.

### Solution to Problem

According to an aspect of the present invention, an ion milling device includes a rotation stage, a movable stage provided on an upper surface of the rotation stage, and a fixed base unit configured to support the rotation stage. The rotation stage includes a first power transmission unit. The fixed base unit includes a second power transmission unit. The ion milling device further includes a member exerting a force for pressing the first power transmission unit and the second power transmission unit against each other.

### Advantageous Effects of Invention

The present invention can provide an ion milling device in which a horizontal movable stage is placed on a sample rotation stage and power can be supplied to the horizontal movable stage.

### BRIEF DESCRIPTION OF DRAWINGS

FIG. 1A is a top view of an ion milling device 100 according to a first embodiment.

FIG. 1B is a front view of the ion milling device 100.

FIG. 1C is an enlarged view of a stage mechanism in FIG. 1B.

FIG. 2A is a schematic view of an ion source 101 adopting a penning scheme and a power supply circuit that applies a control voltage to an electrode component of the ion source 101.

FIG. 2B is a diagram illustrating a beam profiler monitor scanning an ion beam emitted from the ion source.

FIG. 2C is a diagram illustrating a profile of the ion beam.

FIG. 2D is a diagram illustrating a processed shape when a rotation center axis of a sample and a center axis of the ion beam become eccentric.

FIG. 3 is a diagram illustrating a processed shape of the sample when the X-coordinate is slightly moved using a stage with the structure illustrated in FIG. 1.

FIG. 4 is a flowchart illustrating a processing procedure of the sample using the stage with the structure in FIG. 1.

FIG. 5 is an enlarged view of a periphery of a stage of an ion milling device 100 according to a second embodiment.

### DESCRIPTION OF EMBODIMENTS

### First Embodiment

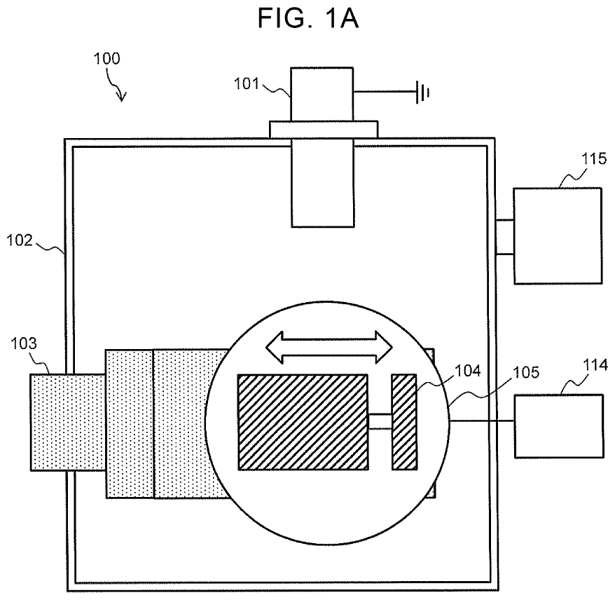

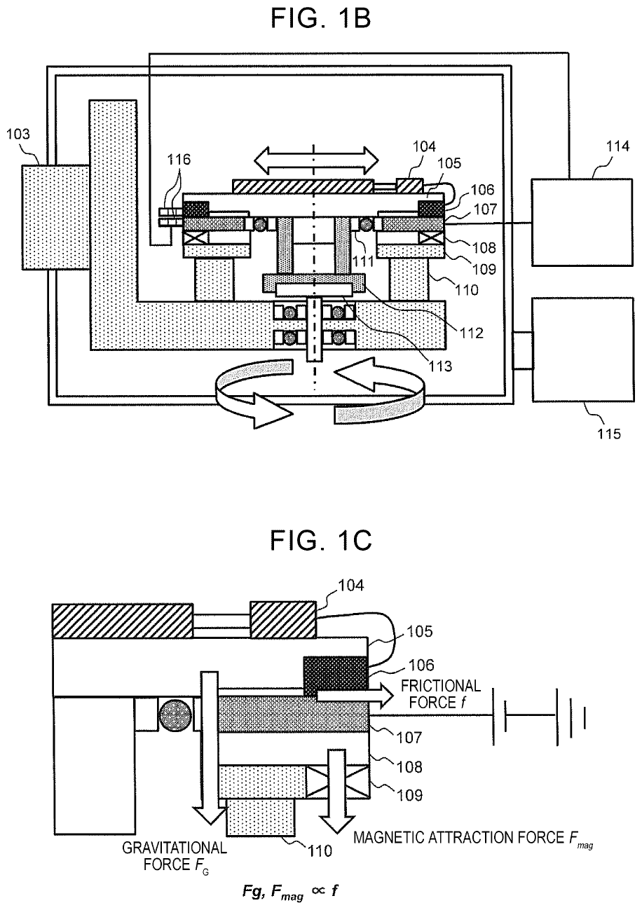

FIG. 1A is a top view of an ion milling device 100 according to a first embodiment of the present invention. The ion milling device 100 includes an ion source 101, a sample chamber 102, a stage tilting unit 103, a single-axis horizontal movable stage 104, a single-axis horizontal movable stage holder 105, a control unit 114, and a vacuum exhaust unit 115.

The ion milling device 100 is used as a preprocessing device to observe a surface of a sample or cross-section of a sample with a scanning electron microscope or transmission electron microscope, and is also applied in semiconductor delayering. During ion milling, the sample chamber 102 is continuously maintained at high vacuum (10⁻³ Pa or less) by the vacuum exhaust unit 115. An externally introduced argon (Ar) gas is ionized by discharge inside the ion source 101 to be radiated as an ion beam onto the sample. The control unit 114 controls each unit included in the ion milling device 100.

FIG. 1B is a front view of the ion milling device 100. The ion milling device 100 further includes a power transmission unit 106 (first power transmission unit) of a rotation stage, a power transmission unit 107 (second power transmission unit) of a fixed base unit, an insulator unit 108, a permanent magnet 109 (contact maintenance member), a fixed base unit 110, a stage rotation bearing 111, a stage rotation unit 112, a stage rotation shaft 113, and a rotation sensor 116.

The sample is placed on the single-axis horizontal movable stage 104. The single-axis horizontal movable stage 104 is mounted on the single-axis horizontal movable stage holder 105. A wiring of the single-axis horizontal movable stage 104 is connected to the power transmission unit 106 of the rotation stage. Since the single-axis horizontal movable stage holder 105 is mounted on the stage rotation unit 112 and the stage rotation shaft 113, the single-axis horizontal movable stage holder 105 can rotate freely (that is, can operate as a rotation stage). The stage rotation unit 112 is fixed inside the stage rotation bearing 111, and the power transmission unit 107 of the fixed base unit is fixed to the outside of the stage rotation bearing 111.

The rotation sensor 116 includes two members. A first member is attached to the fixed base unit 110 side (for example, the power transmission unit 107), while a second member is attached to the rotation stage side (for example, the power transmission unit 106). The second member rotates as the rotation stage rotates. The first member detects the rotation of the second member. For example, the second member may be formed of a permanent magnet, and the first member is configured as a sensor that detects a magnetic force whenever the second member approaches. Accordingly, it is possible to detect rotation of the rotation stage. Since the first member functions as a sensor, it is desirable to place the first member at a position at which power can be supplied (in this example, in contact with the power transmission unit 107). As long as the rotation sensor 116 can detect the rotation of the rotation stage, the present invention is not limited to the configuration illustrated in FIG. 1B.

FIG. 1C is an enlarged view of a stage mechanism in FIG. 1B. A magnetic material (such as Fe or Ni) is embedded in the power transmission unit 106 of the rotation stage. As illustrated in FIG. 1C, the power transmission unit 106 is attracted by the permanent magnet 109 placed with the insulator unit 108 interposed between the power transmission unit 107 and permanent magnet 109. Accordingly, the power transmission unit 106 of the rotation stage is able to rotate through sliding motion while maintaining close contact with the power transmission unit 107.

The power transmission unit 107, insulator unit 108, and the permanent magnet 109 are fixed to the fixed base unit 110. By supplying power from the control unit 114 to the power transmission unit 107, the single-axis horizontal movable stage 104 can operate via the power transmission unit 106 of the rotation stage.

In addition to an attractive force F_{mag} of the magnet, the gravitational force F_{g} increases when a mass of the sample increases. Therefore, a frictional force f acting between the power transmission unit 106 of the rotation stage and the power transmission unit 107 of the fixed base unit increases in proportion to such forces. At this point, depending on a maximum torque value of a motor that rotates the stage, there is a risk of the stage not being rotated. When the stage is not rotated, the non-rotation is fed back from the rotation sensor 116 provided on the side to the control unit 114, and the rotation is stopped.

In the present embodiment, the single-axis horizontal movable stage is included, but a two-axis horizontal movable stage may be included. Since a purpose of the permanent magnet 109 is to attract the power transmission unit 106 of the rotation stage and bring it into contact with the power transmission unit 107 of the fixed base unit. Therefore, it is preferable to use a magnet such as a samarium-cobalt magnet with low magnetic force.

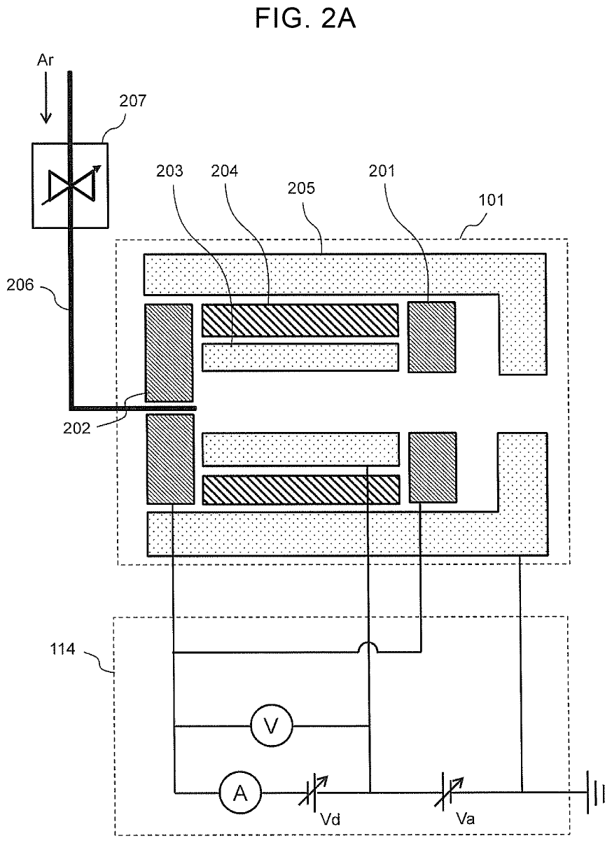

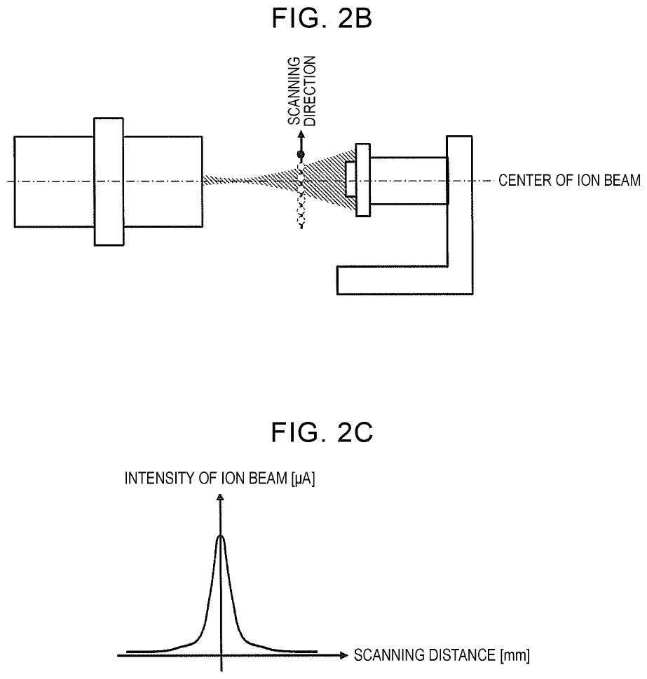

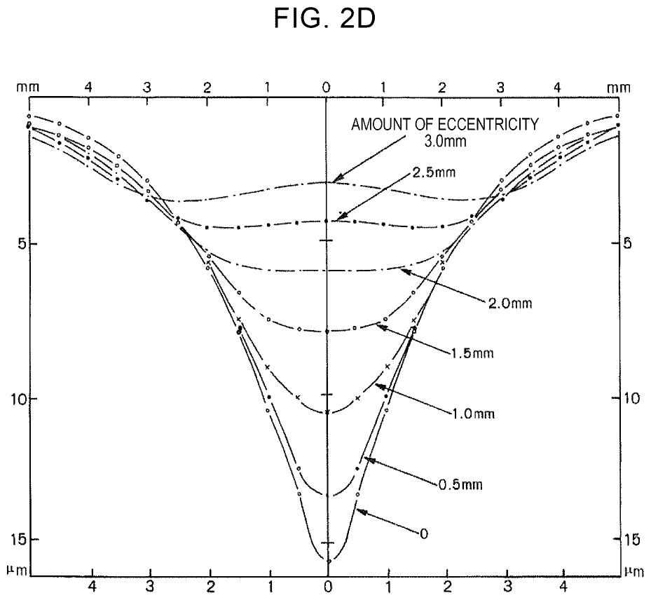

FIG. 2A is a schematic view of the ion source 101 adopting a penning scheme and a power supply circuit that applies a control voltage to an electrode component of the ion source 101. The ion source 101 includes a first cathode 201, a second cathode 202, an anode 203, a permanent magnet 204, an acceleration electrode 205, a gas piping 206, and a gas flow control unit 207 as a main configuration.

To generate an ion beam, an argon gas is injected into the ion source 101 through the gas piping 206. Inside the ion source 101, the first cathode 201 and the second cathode 202 held at the same potential are arranged to face each other via the permanent magnet 204. The anode 203 is located between the first cathode 201 and the second cathode 202. When a discharge voltage V_{d} is applied from a high-voltage power supply within the control unit 114 to the first cathode 201, the second cathode 202, and the anode 203, electrons are generated. The generated electrons are subjected to the Lorentz force due to the permanent magnet 204 located in the ion source 101, and thus the electrons undergo spiral motion.

The electrons collide with the argon gas injected from the gas piping 206 by being controlled by the gas flow control unit 207 and are ionized into plasma to generate argon ions. An acceleration voltage Vₐ from the high-voltage power supply included in the control unit 114 is applied between the anode 203 and the acceleration electrode 205. Accordingly, the generated argon ions are extracted by the acceleration electrode 205 and are emitted as an ion beam.

FIG. 2B illustrates a beam profiler monitor scanning the ion beam emitted from the ion source.

FIG. 2C illustrates a profile of the ion beam. As illustrated in FIG. 2B, when the ion beam is scanned by the beam profiler monitor, a profile following a Gaussian distribution is obtained, as illustrated in FIG. 2C. Accordingly, when the rotation center axis of the sample and the center axis of the ion beam are aligned, the processed shape conforms to the beam profile.

FIG. 2D illustrates a processed shape when the rotation center axis of the sample and the center axis of the ion beam become eccentric. By causing eccentricity, a wider processing area can be achieved. As the amount of eccentricity increases, a flat surface is obtained (with eccentricity of 2.0 mm in FIG. 2D), but excessive eccentricity causes the flat surface to be lost (with eccentricities of 2.5 mm and 3.0 mm in FIG. 2D). By applying this result, it is possible to perform linear processing by moving the sample while maintaining alignment between the rotation center axis of the sample and the center axis of the ion beam. As illustrated in FIG. 2D, when the eccentricity increases, the processed shape gradually deviates from a Gaussian distribution. Therefore, in consideration of ease of control on the processed shape, the eccentricity is preferably zero. That is, it is desirable that the rotation center axis of the sample and the center axis of the ion beam are aligned.

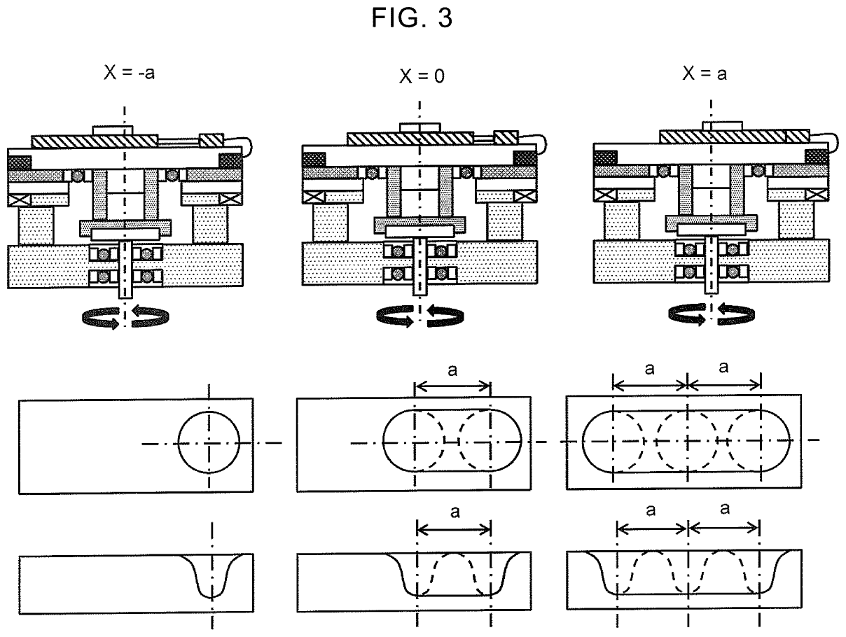

FIG. 3 illustrates a processed shape of the sample when the X-coordinate is slightly moved using the stage with the structure illustrated in FIG. 1. It is assumed that the rotational axis of the sample is aligned with the center axis of the ion beam and is continuously rotated. The X-coordinate of the processing start point is set to −a (mm). At this position, the processed shape follows the shape of the beam profile and is therefore milled into a shape that can be approximated as a conical shape. When the X-axis is moved within the range of −a to 0 (mm), it can be confirmed that the processed shape of the sample is an elongated hole shape in a top view. The length of the elongated hole (defined as a distance between the centers of the circles at both ends at that time) becomes a (mm) which is equal to an X-axis movement distance. Similarly, when the X-coordinate is moved within the range of −a to a (mm), the processed shape also becomes an elongated hole with a length of 2a. Although the description has been made using a single-axis movable stage, a two-axis movable stage may be used to further expand a movable range.

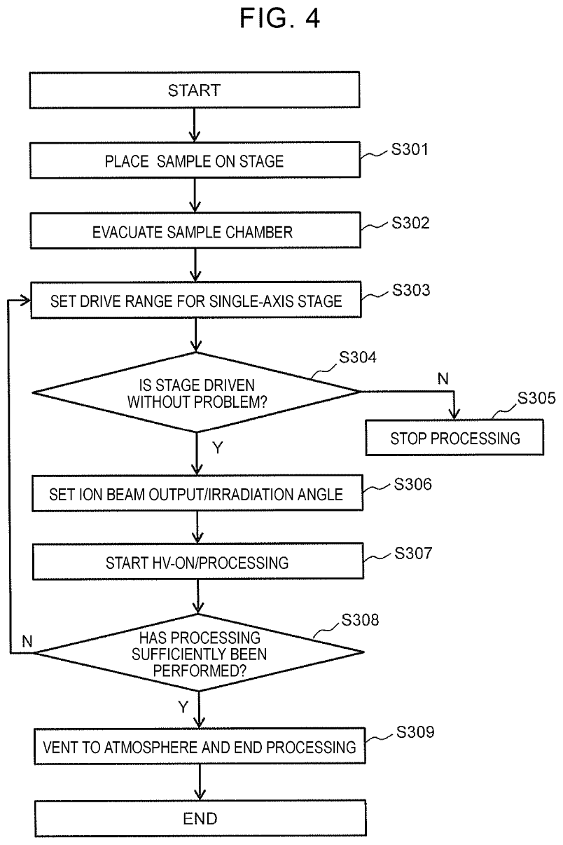

FIG. 4 is a flowchart illustrating a processing procedure of the sample using the stage with the structure in FIG. 1. Each step is performed by the control unit 114 controlling each unit. Hereinafter, each step in FIG. 4 will be described.

S301: The sample is placed on the single-axis horizontal movable stage 104. The processing start point is determined in consideration of alignment between the rotational axis of the sample and the center of the ion beam.

S302: The sample chamber 102 is evacuated using the vacuum exhaust unit 115.

S303: The drive range for the single-axis horizontal movable stage 104 is set. In principle, during processing, the single-axis horizontal movable stage 104 reciprocates within the drive range set in this flow. In the case of a two-axis horizontal stage, the drive range may be set so that the movement forms a continuous stroke and the stage reciprocates between the start and end points.

S304: It is confirmed whether the movable stage can be driven without problem within the drive range set in S303, including a rotary contact portion (referring to a portion where the power transmission unit 106 of the rotation stage and the power transmission unit 107 of the fixed base unit are rotated while coming into contact with each other). When the single-axis horizontal movable stage 104 does not move, a sensor embedded in the single-axis horizontal movable stage 104 performs detection, and then the process proceeds to S305. When the rotary contact portion does not move, the rotation sensor 116 performs detection, and then the process proceeds to S305. When movement is performed without problem, the process proceeds to S306.

S305: The processing stops.

S306: The output conditions for the ion beam are set and the stage tilting unit 103 is tilted to set an irradiation angle of the ion beam.

S307: The ion beam is output and the processing starts.

S308: It is confirmed whether the processing has been sufficiently performed based on the drive range set in S303. When the processing is insufficient, the process returns to S303, the drive range for the single-axis horizontal movable stage 104 is reset, and the processing resumes. When the processing has been sufficiently performed, the process proceeds to S309.

S309: The sample chamber 102 is vented to the atmosphere and the processing ends.

### First Embodiment: Conclusion

In the ion milling device 100 according to the first embodiment, the power transmission unit 106 is placed in the single-axis horizontal movable stage holder 105 included in the rotation stage, and power is supplied to the single-axis horizontal movable stage 104 via the power transmission units 106 and 107. A magnetic material is embedded in the power transmission unit 106, and the permanent magnet 109 attracts the power transmission unit 106 to generate a force for pressing the power transmission units 106 and 107 against each other, and thus close contact between the power transmission units 106 and 107 is maintained. Accordingly, the rotation stage can be rotated while sliding. This structure rotates while coming into contact with a conductive unit as in the rotary contact type wiring. Accordingly, a single-axis movable stage can be installed on the sample rotation stage without using mercury.

### Second Embodiment

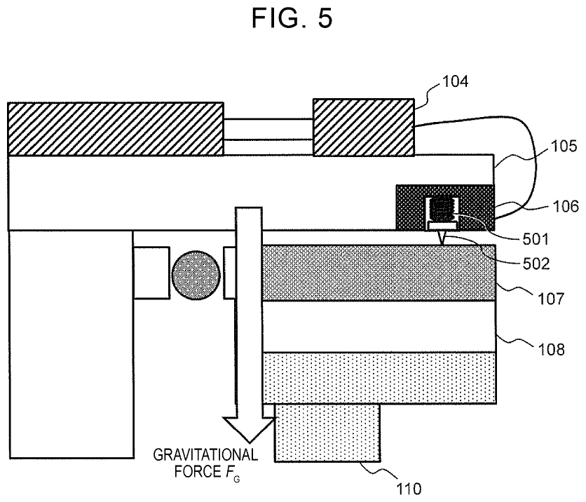

FIG. 5 is an enlarged view of a periphery of a stage of an ion milling device 100 according to a second embodiment of the present invention. In the first embodiment, a structure in which a magnet is embedded in the fixed base unit to ensure contact between the power transmission units 106 and 107 has been described. In the second embodiment, instead of embedding a magnet in the fixed base unit, a pin 502 with a compression spring 501 is incorporated into the power transmission unit 106 of the rotation stage. When the power transmission units 106 and 107 are slid to each other, the incorporated spring presses the pin against the power transmission unit 107, ensuring constant contact between the two units. As in the first embodiment, rotation motion is enabled while maintaining contact between the power transmission units 106 and 107, and power can be supplied to the single-axis horizontal movable stage 104. The other configurations are the same as those in the first embodiment. The compression spring 501 and the pin 502 serve as a contact maintenance member that maintains the contact by exerting a force for pressing the power transmission units 106 and 107 against each other.

The power transmission unit 107 supports the power transmission unit 106 at a point via the pin 502 (protrusion). Accordingly, it is possible to minimize the contact area between the power transmission units 106 and 107. Accordingly, frictional heat generated during rotation of the rotation stage can be inhibited. Power supplied from the power transmission unit 107 is transmitted to the single-axis horizontal movable stage 104 via the pin 502 and the compression spring 501 (and a wiring).

### Modified Examples of Present Invention

The present invention is not limited to the above-described embodiments and includes various modified examples. For example, the above-described embodiments have been described in detail to clearly illustrate the present invention, and it is not necessary to include all the configurations as described. Modifications are possible without departing from the gist of the present invention.

In the second embodiment, the power transmission unit 107 that supports the power transmission unit 106 at a point via the pin 502 has been described. A similar structure can also be applied to the first embodiment. That is, the bottom surface of the power transmission unit 106 may partially protrude to form a protrusion, and the power transmission unit 107 can be configured to support the power transmission unit 106 at a point via the protrusion. Accordingly, it is possible to inhibit frictional heat, as in the second embodiment.

In the above embodiments, in the flowchart up to completion of the sample processing illustrated in FIG. 4, continuous processing has been performed while reciprocating the movable stage within the preset drive range of the single-axis horizontal movable stage. However, planar milling of the sample at a specific point may be performed, and after the processing completes, the single-axis horizontal movable stage may move to another point and planar milling may be performed again.

In the above embodiments, the control unit 114 may be configured using hardware such as a circuit device that implements functions, or may be configured by causing an arithmetic device such as a central processing unit (CPU) to execute software that implements the functions.

### REFERENCE SIGNS LIST

100: ion milling device
104: single-axis horizontal movable stage
105: single-axis horizontal movable stage holder
106: power transmission unit of rotation stage
107: power transmission unit of fixed base unit
108: insulator unit
109: permanent magnet
114: control unit
501: compression spring
502: pin

1-9. (canceled)

10. An ion milling device that irradiates a sample with an ion beam, the ion milling device comprising:
a rotation stage configured to rotate about a rotational axis;
a movable stage provided on an upper surface of the rotation stage and configured to move in a direction that is not parallel to the rotational axis; and
a fixed base unit configured to support the rotation stage,
wherein the rotation stage includes a first power transmission unit capable of transmitting power to the movable stage,
wherein the fixed base unit includes a second power transmission unit supplied with power from a power supply,
wherein the first power transmission unit and the second power transmission unit are configured to transmit the power supplied by the power supply to the movable stage by coming into contact with each other,
wherein the ion milling device further comprises a contact maintenance member that maintains contact between the first power transmission unit and the second power transmission unit by exerting a force for pressing the first power transmission unit and the second power transmission unit against each other,
wherein the ion milling device further comprises a sensor,
wherein the sensor includes a first member attached to the fixed base unit and a second member attached to the rotation stage,
wherein the second member rotates along with the rotation stage, and
wherein the first member is supplied with power via the second power transmission unit to detect rotation of the second member.

11. The ion milling device according to claim 10,
wherein the first power transmission unit includes a portion made of a magnetic material,
wherein the contact maintenance member is formed of a magnet that exerts a magnetic force for attracting the magnetic material to exert a force for pressing the first power transmission unit and the second power transmission unit against each other.

12. The ion milling device according to claim 10,
wherein the contact maintenance member is formed of a pin into which a compression spring is incorporated, and
wherein the contact maintenance member is configured to cause the pin to exert a force for pressing the first power transmission unit and the second power transmission unit against each other through working of the compression spring.

13. The ion milling device according to claim 10,
wherein the movable stage is configured such that the sample is placed,
wherein the ion milling device further comprises an ion source configured to emit the ion beam,
wherein the ion milling device further comprises a control unit configured to control the rotation stage and the movable stage, and
wherein the control unit processes the sample with the ion beam by aligning a beam center axis of the ion beam with the rotational axis and then moving the movable stage.

14. The ion milling device according to claim 10,
wherein the ion milling device further comprises a control unit configured to control an operation of the ion milling device, and
wherein the control unit stops processing the sample with the ion beam when the sensor detects that a rotation motion of the rotation stage is not a defined motion.

15. The ion milling device according to claim 10,
wherein the first power transmission unit includes a protrusion coming into contact with the second power transmission unit, and
wherein the second power transmission unit is configured to support the first power transmission unit at a point via the protrusion.

16. The ion milling device according to claim 12,
wherein the first power transmission unit includes a protrusion coming into contact with the second power transmission unit,
wherein the second power transmission unit is configured to support the first power transmission unit at a point via the protrusion, and
wherein the protrusion is configured with the pin.

17. The ion milling device according to claim 13,
wherein the control unit processes the sample into a line shape using the ion beam by moving the movable stage while rotating the rotation stage.
